(19) United States
(12) Patent Application Publication
(10) Pub. No.: US 2007/0272921 A1
(43) Pub. Date: Nov. 29, 2007

(54) Multicolor Organic Light-Emitting Device

(75) Inventor: Manabu Furugori, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/677,292

(22) Filed: Feb. 21, 2007

(30) Foreign Application Priority Data
Mar. 31, 2006 (JP) 2006-096874

(51) Int. Cl. H05B 33/22; H01L 33/00

(52) U.S. Cl. 257/40; 257/E33.001

(57) ABSTRACT

Provided is a multicolor organic EL display having plural organic EL devices arranged on a substrate. The multicolor organic light-emitting device includes a substrate; plural organic light-emitting elements provided on the substrate, including a first organic light-emitting element of first emission color and a second organic light-emitting element of second emission color different from the first emission color, wherein the first organic light-emitting element has a first electrode of a first material, an organic compound layer including at least a light-emitting layer, and a light transmissive, second electrode, provided sequentially in the mentioned order from the substrate side, and wherein the second organic light-emitting element has a first electrode of a second material different in reflectance or phase shift from the first material, an organic compound layer including at least a light-emitting layer, and the second electrode, sequentially provided in the mentioned order from the substrate side.

### BACKGROUND OF THE INVENTION

1. Field of the Invention

The present invention relates to a multicolor organic light-emitting device (hereafter, sometimes also referred to as “display device”) which is constructed by arranging a plurality of organic light-emitting elements (hereafter, sometimes simply referred to as “light-emitting elements”) on a substrate.

2. Description of the Related Art

Recently, display devices using a light-emitting element have attracted attention. The display devices have characteristics of spontaneous emission, a wide view angle, and low power consumption and also have such a high response speed as to respond also to high-speed movie display.

Here, an example of a light-emitting element is shown in FIG. 1. A substrate 11 having a first electrode formed thereon is used. The element has a structure in which a first electrode 12, a plurality of organic compound layers 13 including a light-emitting layer, and a second electrode 14 are stacked sequentially on the substrate 11. Further, the organic compound layer 13 has a light-emitting layer 132, and as functional layers, a first functional layer 131 (e.g., a hole injection layer, or a hole-transporting layer) on the first electrode 12, and a second functional layer 133 (e.g., an electron injection layer, or an electron-transporting layer) on the second electrode 14 side according to circumstances.

A display device is constructed by arranging a plurality of such light-emitting elements. In particular, it is possible to construct a full color display device by arranging a plurality of light-emitting elements whose emission colors are different from each other.

A display device disclosed in Japanese Patent Application Laid-Open No. 2000-323277 strengthens light emission and extracts light by setting the film thickness of a functional layer of an organic compound layer to an appropriate value for the emission color of each light-emitting element.

A display device disclosed in Japanese Patent Application Laid-Open No. 2005-116516 strengthens light emission and extracts light by setting an appropriate thickness of a transparent anode for the emission color which is intended to be extracted from each light-emitting element.

However, in the display device of Japanese Patent Application Laid-Open No. 2000-323277, it is necessity to change not only the film thickness of a light-emitting layer but also the film thicknesses of functional layers such as a hole-transporting layer, an electron-transporting layer or an electron injection layer for each of the light-emitting elements of different emission colors. Therefore, when forming films by evaporation using metal masks, the frequency of mask exchange increases, thus reducing the productivity. In this way, when forming films by evaporation using metal masks, it is desirable that the film thicknesses of layers other than light-emitting layers which essentially require separate coating are common to each other.

With the display device of Japanese Patent Application Laid-Open No. 2005-116516, the film formation process becomes easy. However, because the same light-emitting layer is formed on the respective light-emitting elements, there is a restriction that it is necessary to use a light-emitting layer which performs white light emission.

### SUMMARY OF THE INVENTION

The present invention provides a multicolor organic light-emitting device whose production method is comparatively easy and which is highly efficient.

In order to solve the problems of the above-mentioned background art, the present invention provides a multicolor organic light-emitting device, which comprises a substrate; a plurality of organic light-emitting elements provided on the substrate, including a first organic light-emitting element of a first emission color and a second organic light-emitting element of a second emission color different from the first emission color, wherein the first organic light-emitting element has a first electrode which is comprised of a first material, an organic compound layer which comprises at least a light-emitting layer, and a second electrode which is light transmissive, provided sequentially in the mentioned order from the substrate side, and wherein the second organic light-emitting element has a first electrode which is comprised of a second material different in reflectance or phase shift from the first material, an organic compound layer which comprises at least a light-emitting layer, and the second electrode, sequentially provided in the mentioned order from the substrate side.

According to the multicolor organic light-emitting device of the present invention, only by changing the reflectance or phase shift of the first electrode, even when functional layers other than a light-emitting layer of each light-emitting element are the same, light of a desired emission color can be extracted with high efficiency from each light-emitting element.

Further features of the present invention will become apparent from the following description of exemplary embodiments with reference to the attached drawings.

### BRIEF DESCRIPTION OF THE DRAWINGS

FIG. 1 is a cross-sectional view of a general organic light-emitting element.

FIG. 2 is a cross-sectional view of a display device of the present invention in which organic light-emitting elements are arranged.

FIG. 3 is a cross-sectional view of another display device of the present invention in which organic light-emitting elements are arranged.

FIG. 4 is a diagram showing organic materials used in Examples and Comparative Examples.

FIG. 5 is a diagram showing the compositions of organic compound layers used in Examples and Comparative Examples.

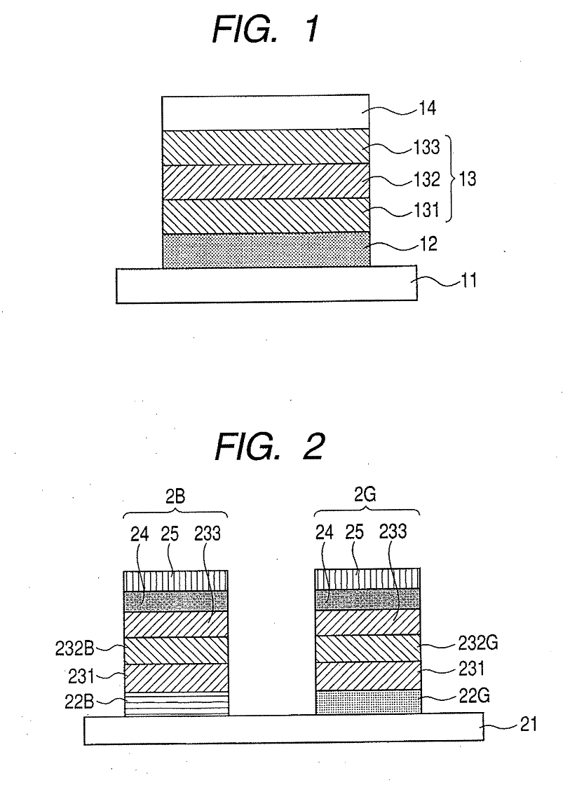

### DESCRIPTION OF THE EMBODIMENTS

The present invention will now be described with respect to embodiments, although it will be readily appreciated that the present invention is not limited to such embodiments.

### Embodiment 1

A multicolor organic light-emitting device shown in FIG. 2 is an example of a multicolor organic light-emitting device which has light-emitting elements 2G and 2B of different emission colors arranged. On a substrate 21, an organic light-emitting element 2G is formed which has a first electrode 22G, an organic compound layer constituted of a first functional layer 231, a light-emitting layer 232G, and a second functional layer 233, and a second electrode 24 stacked on the substrate 21 and is encapsulated by a transparent protective layer 25. Similarly, an organic light-emitting element 2B is formed which has a first electrode 22B, an organic compound layer constituted of a first functional layer 231, a light-emitting layer 232B, and a second functional layer 233, and a second electrode 24 stacked on the substrate 21, and is encapsulated by a transparent protective layer 25. Incidentally, the organic compound layer of the present embodiment is formed by vacuum evaporation under a vacuum of 5×10⁻⁴ Pa. The evaporation is performed using a metal mask according to circumstances, and a pattern is formed. As for the respective organic compound layers, the light-emitting layer 232G and light-emitting layer 232B are constructed so as to emit green light and blue light, respectively.

The first electrodes 22G and 22B are different from each other in reflectance or phase shift of light reflection. It is generally known that the reflectances and phase shifts of the first electrodes 22G and 22B are each dependent on the refractive index n and the extinction coefficient k of the material of a reflective interface. This is because when the materials of the first electrodes 22G and 22B are different, the values of n and k are also different.

The reflectances are set by selecting the wavelengths of lights which are emitted by the organic light-emitting elements 2G and 2B. For example, the reflectance of the first electrode 22G of the organic light-emitting element 2G is set based on the wavelength of an emission peak of the organic light-emitting element 2G, and the reflectance of the first electrode 22B of the organic light-emitting element 2B is set based on the wavelength of an emission peak of the organic light-emitting element 2B. Here, since there are many cases where light within a shorter wavelength region is influenced more easily in absorption, phase change, and the like at the time of reflection, it is preferable to select an emission peak wavelength which is the shortest wavelength. In addition, it is desirable that the reflectances of the first electrodes 22G and 22B are high, and in particular, the reflectance at a wavelength at or around an emission peak in the wavelength region in which light is intended to be extracted from the organic light-emitting element 2G (2B) is high.

As the first electrodes 22G and 22B, it is possible to use metal layers of Ag, Al, Au, Cr, Cu, and the like. For example, it is possible to use Ag for the first electrode 22G of the light-emitting element 2G, and Al for the first electrode 22B of the organic light-emitting element 2B. In addition, when an organic light-emitting element 2R which emits red light is arranged on the substrate 21 as described later, it is possible to use Au whose reflectance at a wavelength of 600 nm or more is high and whose reflectance at a wavelength of less than 600 nm is low, for a first electrode 22R of an organic light-emitting element 2R, which makes it possible to expect the effect of suppressing reflection of blue light and green light which are incident from the outside of the organic light-emitting element 2R.

The metals are not limited to the above-mentioned ones, and other metals or alloys which provide appropriate reflectances or phase shifts to the respective organic light-emitting elements 2G, 2B, (and 2R) may also be used. In addition, even when the same material is used, there are cases where different reflectances or phase shifts can be obtained due to differences in surface shape or film quality of the first electrodes 22G, 22B, (and 22R).

The first electrodes 22G and 22B each may be constituted of a stack of a light reflective metal layer and a transparent electrode layer. It is necessary for the first electrodes 22G and 22B to inject carriers of holes or electrons into organic compound layers. However, when a first electrode constructed of a metal layer and a transparent electrode layer is used, even in a case where the metal layer has no carrier injection property, it is possible to inject carriers into an organic compound layer by using a transparent electrode layer which has carrier injection property. For example, a first electrode of such a stack structure can be obtained by forming an IZO film as a transparent conductive film on an Al metal film or an Ag metal film. Comparing the case of providing an IZO film on an Al metal film to prepare a first electrode and the case of providing an IZO film on an Ag metal film to prepare a first electrode, there is a phase difference of about 0.15 n at the time of reflection at near 480 nm.

The material or film thickness of the functional layer 231 provided on the first electrodes 22G and 22B may differ for each of the organic light-emitting elements 2G and 2B. However, when the material or film thickness of the functional layer 231 is changed for each of the organic light-emitting elements 2G and 2B, it is necessary to perform evaporation while changing a metal mask for each of the organic light-emitting elements 2G and 2B, so that the production process becomes complicated. Therefore, it is desirable that the functional layers 231 of the respective organic light-emitting element 2G and 2B are the same.

Meanwhile, it is assumed that a phase shift which is generated when light emitted by the light-emitting layer 232G (232B) is reflected by the first electrode 22G (22B) is Φ₁ radians, and an optical path from a center of a light-emitting region of the light-emitting layer 232G (232B) to the first electrode 22G (22B) is L₁. In addition, when it is assumed that the wavelength of light, which is intended to be extracted, of the above-mentioned light is λ, higher efficiency can be obtained by having the optical path L₁ which satisfies a condition represented by the following equation (a):

2L₁=nλ+(Φ₁/2π)λ (n is an integer) (a).

### Incidentally, the optical path L₁ is a product of the refractive index of a medium which transmits light and a distance.

Therefore, by using, respectively, appropriate first electrodes 22G and 22B with different Φ₁'s for the organic light-emitting elements 2G and 2B with different emission peaks, it is possible to satisfy the above-mentioned condition or to reduce a deviation from an optimum L₁ even when the functional layers 231 have the same film thicknesses. In addition, when the light-emitting regions in the light-emitting layers 232G and 232B are dependent on the compositions or doping concentrations of the light-emitting layers 232G and 232B, it is also possible to set compositions or film thicknesses appropriately to thereby satisfy the above-mentioned equation (a).

The present invention can also be applied to the case of a white-light-emitting layer that has a plurality of emission peaks. Even when the functional layers 231 and white-light-emitting layers are, respectively, the same for the organic light-emitting elements 2G and 2B, by setting first electrodes 22G and 22B with different Φ₁'s for the respective light-emitting elements 2G and 2B, the shapes of the emission spectra can be changed to thereby extract a plurality of different colors from the same white-light-emitting layers. Furthermore, by using a color filter or the like, blue light and green light with high color purity can be extracted from the same light-emitting layers.

When the second electrode 24 of the organic light-emitting element 2G (2B) has light reflectivity, by allowing light emitted by the light-emitting layer 232G (232B) to resonate between the first electrode 22G (22B) and the second electrode 24 as a resonance part, high efficiency and desired chromaticity can be obtained. As the second electrode 24, metals with high reflectance such as metal thin films of Ag and Al can be used. Further, it is also possible to dispose a material with refractive index lower than that of the second electrode 24 outside the second electrode 24 and thereby to utilize reflection which occurs at an interface. For example, when gas such as nitrogen is disposed on the upper portion of a transparent electrode such as an ITO film or an IZO film, reflection occurs at an interface between the transparent electrode and the gas, light reflectivity can be given to the second electrode 24.

When the second electrode 24 has light reflectivity, it is assumed that the sum of phase shifts which are generated when light emitted by the light-emitting layer 232G (232B) is reflected by the first electrode 22G (22B) and the second electrode 24 is Φ₂ radians, and that the optical path of the above-mentioned resonance part is L₂. In addition, when the wavelength of light, which is intended to be extracted, of the above-mentioned light is represented by λ, higher efficiency can be obtained by setting the optical path L₂ which satisfies the condition represented by the following equation (b)

2L₂=mλ+(Φ₂/2π)λ (m is an integer) (b).

Generally, it is effective to set λ at near a emission wavelength peak of the light-emitting layer 232G (232B). When the optical path L₂ is set so as to satisfy the above-mentioned equation (b), it is possible, other than the change of the phase shifts of the first electrodes 22G and 22B of the respective light-emitting elements 2G and 2B, to change the film thicknesses of the functional layers 231 or the light-emitting layers 232G and 232B. However, when the film thicknesses of the organic compound layers are different for the respective organic light-emitting element 2G and 2B, the production process becomes more complicated. Therefore, it is desirable to perform the production such that the film thicknesses of the light-emitting layers 232G and 232B of the respective organic light-emitting elements 2G and 2B each satisfy the above-mentioned equation (b), and the organic compound layers other than the light-emitting layers 232G and 232B are the same for the respective organic light-emitting elements 2G and 2B.

As described above, according to the display device of the present invention, even when the functional layers other than the light-emitting layers are the same for the respective organic light-emitting elements, only by allowing the reflectances or phase shifts of the first electrodes to differ from each other, it becomes possible to extract a desired emission color from each organic light-emitting element with high efficiency.

### Embodiment 2

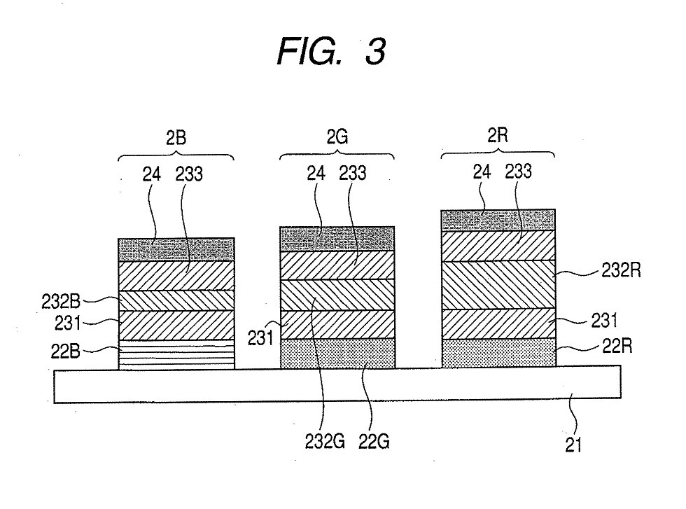

Incidentally, in Embodiment 1, the organic light-emitting element 2G which emits green light and the organic light-emitting element 2B which emits blue light are arranged on the substrate 21. However, as shown in FIG. 3, a full color display device can also be provided which is constructed by further adding an organic light-emitting element 2R which emits red light and by arraying on a substrate a plurality of organic light-emitting element groups which are each constituted of organic red-, green-, and blue-light-emitting elements 2R, 2G, and 2B.

In the case of a full color display device, color reproduction range compared to the National Television System Committee (NTSC) standard becomes one of factors which determine the image quality. When performing full color display by use of the organic red-, green-, and blue-light-emitting elements 2R, 2G, and 2B, as the light-emitting element 2R, an organic light-emitting element with an emission color near chromaticity coordinates (0.67, 0.33) has high color purity and is preferable for full color display. As the light-emitting element 2G, an organic light-emitting element with an emission color near chromaticity coordinates (0.21, 0.71) has high color purity and is preferable for full color display. As the light-emitting element 2B, an organic light-emitting element with an emission color near chromaticity coordinates (0.14, 0.08) has high color purity and is preferable for full color display. By setting L₁ and L₂ corresponding to desired emission colors, the shapes of emission spectra can be changed to adjust emission colors, thereby providing a display device having a wide color reproduction range.

In the present invention, although the method of forming electrode patterns in which the first electrodes are different is not limited particularly, it is possible to use a general method, such as a method of using photolithography and etching, or a method of forming a patter using a metal mask during evaporation/sputtering.

In the present invention, the second electrode may be an IZO film, an ITO film, or the like which is formed by sputtering or the like, and also may be formed by evaporation or sputtering of a metal such as Ag. When a moisture resistant layer is provided on the second electrode, use of a transparent, water/gas impermeable material is desirable. For example, a silicon nitride thin film can be formed by CVD or sputtering.

### EXAMPLES

### Example 1

As shown in FIG. 2, a multicolor organic light-emitting device in which the organic light-emitting elements 2G and 2B constituted of the first electrodes 22G and 22B, first functional layers 231, light-emitting layers 232G and 232B, second functional layers 233, second electrodes 24, and transparent protective layers 25 were arranged on a glass substrate 21 was produced.

Specifically, an Ag layer of 100 nm in thickness and an IZO film of 20 nm in thickness were formed on the glass substrate 21 to form the first electrode 22G. Similarly, an Al film of 100 nm in thickness and an IZO film of 20 nm in thickness were formed on the glass substrate 21 to form the first electrode 22B. On the first electrode 22G (22B), a hole-transporting layer of 20 nm in thickness was formed commonly to the light-emitting elements 2G and 2B as the first functional layer 231. The light-emitting layer 232G of 30 nm in thickness was formed on the first functional layer 231 of the organic light-emitting element 2G, and the light-emitting layer 232B of 30 nm in thickness was formed on the first functional layer 231 of the organic light-emitting element 2B. Furthermore, an electron-transporting layer of 20 nm in thickness was formed commonly to the organic light-emitting elements 2G and 2B as the second functional layer 233. As the second electrode 24, an IZO film of 60 nm in thickness as a transparent electrode was formed thereon by sputtering. A silicon nitride film as the transparent protective layer 25 was formed in a thickness of 6 μm by a CVD method on the second electrode 24.

When a voltage was applied to the multicolor organic light-emitting device to cause light emission, the chromaticity of the organic light-emitting element 2B at this time was (0.14, 0.11), and the efficiency was 2.0 cd/A. Further, the chromaticity of the organic light-emitting element 2G was (0.29, 0.63), and the efficiency was 9.7 cd/A.

### Comparative Example 1

A multicolor organic light-emitting device was produced by following the same procedure as in Example 1 with the exception that the first electrodes 22G and 22B are formed of Ag films of 100 nm in thickness. When a voltage was applied to the display device to cause light emission, the light-emitting element 2G had the same chromaticity and efficiency as those of Example 1. However, the chromaticity of the organic light-emitting element 2B was (0.15, 0.14) and the efficiency was 2.5 cd/A, so that the color purity of the organic light-emitting element 2B lowered. When the first electrodes and the first functional layers are, respectively, the same for the organic light-emitting elements 2G and 2B, the above-mentioned equation (a) is not satisfied at or near a blue-light wavelength, and the color purity of the organic light-emitting element 2B was lower.

### Comparative Example 2

A multicolor organic light-emitting device was produced by following the same procedure as Comparative Example 1 with the exception that the film thickness of the first functional layer 231 was not 20 nm but 10 nm. When a voltage was applied to the multicolor organic light-emitting device to cause light emission, the chromaticity of the organic light-emitting element 2B was (0.14, 0.11) and the efficiency was 2.1 cd/A, which were the same as the chromaticity and efficiency of Example 1. However, the chromaticity of the organic light-emitting element 2G was (0.28, 0.63) and the efficiency was 9.0 cd/A, so that the efficiency of the organic light-emitting element 2G lowered.

As described in detail in Example 1 and Comparative Examples 1 and 2, in the case where the first electrode 22B had an Al layer and the first electrode 22G had an Ag layer, even when the first functional layers were the same, both the light-emitting elements 2G and 2B could satisfy the equation (a) and good chromaticity and efficiency were obtained.

On the other hand, in the case where the first electrodes 22G and 22B each had an Ag layer, when the thickness of the first functional layer 231 was adjusted such that the organic light-emitting element 2B satisfied the above-mentioned equation (a) to give high color purity, the efficiency of the organic light-emitting element 2G lowered.

### Example 2

As shown in FIG. 3, a multicolor organic light-emitting device in which organic light-emitting elements 2R, 2G and 2B each constituted of a first electrode 22R (22G, 22B), a first functional layers 231, a light-emitting layer 232R (232G, 232B), a second functional layer 233, and a second electrode 24 were arranged on a glass substrate 21 was produced.

Specifically, an Ag layer of 100 nm in thickness and an IZO film of 20 nm in thickness were formed on the glass substrate 21 to form each of the first electrodes 22R and 22G. Similarly, an Al film of 100 nm in thickness and an IZO film of 20 nm in thickness were formed on the glass substrate 21 to form the first electrode 22B. On the first electrode 22R (22G, 22B), a hole-transporting layer of 20 nm in thickness was formed commonly to the light-emitting elements 2R, 2G and 2B as the first functional layer 231. A light-emitting layer 232R of 70 nm in thickness was formed on the first functional layer 231 of the organic light-emitting element 2R, a light-emitting layer 232G of 30 nm in thickness was formed on the first functional layer 231 of the organic light-emitting element 2G, and the light-emitting layer 232B of 20 nm in thickness was formed on the first functional layer 231 of the organic light-emitting element 2B. Furthermore, an electron-transporting layer of 50 nm in thickness was formed commonly to the organic light-emitting elements 2R, 2G and 2B as the second functional layer 233. As the second electrode 24, an IZO film of 60 nm in thickness as a transparent electrode was formed thereon by sputtering. The second electrode 24 was not provided with a transparent protective layer on the top thereof and but sealed with a glass cap under nitrogen atmosphere such that the second electrode 24 was in contact with nitrogen gas (not shown). Since there is a comparatively large refractive index difference at an interface between the second electrode 24 and the nitrogen gas, reflection occurs at the interface between the second electrode 24 and the nitrogen gas, so that the second electrode 24 has light reflectivity. When a voltage was applied to the display device to cause light emission, the chromaticity of the organic light-emitting element 2R at this time was (0.65, 0.35), and the efficiency was 10.5 cd/A. Further, the chromaticity of the organic light-emitting element 2G was (0.26, 0.68), and the efficiency was 4.3 cd/A. Moreover, the chromaticity of the organic light-emitting element 2B was (0.15, 0.12), and the efficiency was 2.3 cd/A. Since each of the organic light-emitting elements 2R, 2G, and 2B has such optical paths L₁ and L₂ as to correspond to the emission color (the above-mentioned equations (a) and (b) are almost satisfied), high efficiency can be obtained with good chromaticity.

### Comparative Example 3

A multicolor organic light-emitting device was produced by following the same procedure as in Example 2 with the exception that the first electrode 22B was formed of a 100 nm thick Ag layer and a 20 nm thick IZO film as was the case with the first electrode 22G of Example 2. When a voltage was applied to the display device to cause light emission, the red- and green-light-emitting elements each had the same chromaticity and efficiency as those of Example 2. However, the chromaticity of the organic light-emitting element 2B was (0.15, 0.20) and the efficiency was 3.8 cd/A, so that the color purity of the organic light-emitting element 2B lowered. When the first electrodes and the first functional layers were, respectively, the same, such optical paths L₁ and L₂ as to correspond to the light emission of the organic light-emitting element 2B were not attained (the above-mentioned equations (a) and (b) were not satisfied), the color purity of blue lowered.

From the above-mentioned Examples and Comparative Examples, it was confirmed that the display device of the present invention could provide a multicolor organic light-emitting device with high color purity of each color in comparison with the display devices of the comparative examples.

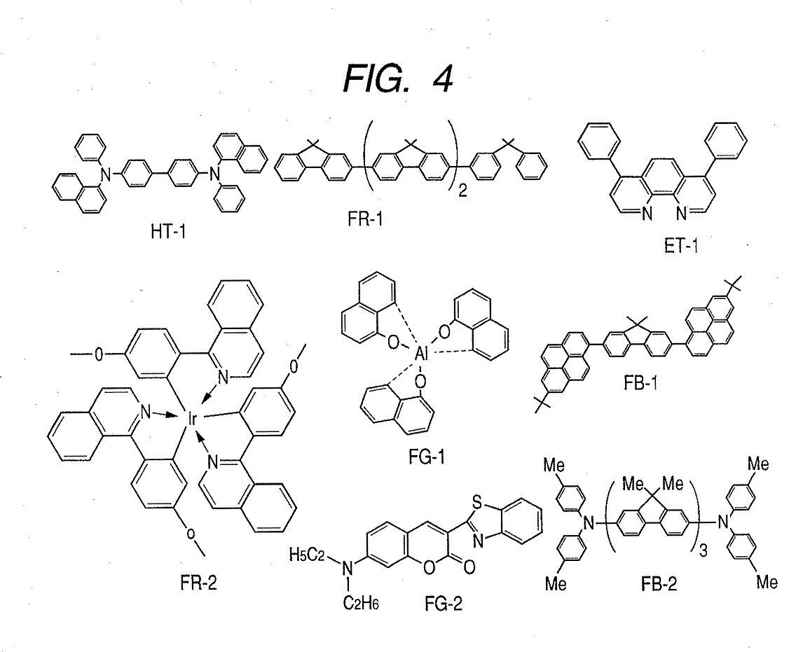

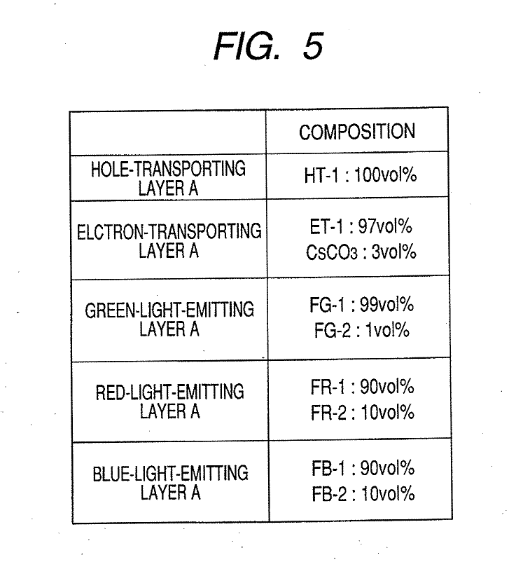

Incidentally, the term “efficiency” employed in the above examples and comparative examples refers to emission efficiency measured at a luminance of 100 cd/cm², and the term “chromaticity” refers to CIE chromaticity coordinates. Furthermore, the organic materials used in the examples and comparative examples are shown in FIG. 4, and the compositions of the respective organic compound layers are shown in FIG. 5. Moreover, the refractive index of the IZO film used in the examples and comparative examples was about 1.9, the refractive index of the organic compound layer was about 1.8, the refractive index of the moisture resistant layer was about 2.0, and the refractive index of the nitrogen gas was about 1.0.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-096874, filed Mar. 31, 2006, which is hereby incorporated by reference herein in its entirety.

What is claimed is:

1. A multicolor organic light-emitting device, comprising:
a substrate;
a plurality of organic light-emitting elements provided on the substrate, including a first organic light-emitting element of a first emission color and a second organic light-emitting element of a second emission color which is different from the first emission color, wherein the first organic light-emitting element has a first electrode which is comprised of a first material, an organic compound layer which comprises at least a light-emitting layer, and a second electrode which is light transmissive, provided sequentially in the mentioned order from the substrate side, and
wherein the second organic light-emitting element has a first electrode which is comprised of a second material different in reflectance or phase shift from the first material, an organic compound layer which comprises at least a light-emitting layer, and the second electrode, sequentially provided in the mentioned order from the substrate side.

2. The multicolor organic light-emitting device according to claim 1, wherein the thickness of the organic compound layer of the first organic light-emitting element and the thickness of the organic compound layer of the second organic light-emitting element are equal to each other.

3. The multicolor organic light-emitting device according to claim 1, wherein, in each of the first organic light-emitting element and the second organic light-emitting element, an optical path L, between a center of a light-emitting region of the light-emitting layer and a reflective surface of the first electrode and a phase shift Φ₁ of the first electrode are adjusted so as to satisfy a condition under which lights emitted by the light-emitting layer strengthen each other.

4. The multicolor organic light-emitting device according to claim 3, wherein the condition is such that the optical path L₁ and the phase shift Φ₁ fulfill the equation 1:
2L₁=nλ+(Φ₁/2π)λ
wherein n is a positive integer, and λ is a wavelength of light which is intended to be extracted.

5. The multicolor organic light-emitting device according to claim 1, wherein the second electrode is a semitransmissive reflective electrode, and wherein, in each of the first organic light-emitting element and the second organic light-emitting element, an optical path L₂ between a reflective surface of the first electrode and a reflective surface of the second electrode and a sum Φ₂ of a phase shift at the first electrode and a phase shift at the second electrode are adjusted so as to satisfy a condition under which light emitted by the light-emitting layer resonates.

6. The multicolor organic light-emitting device according to claim 5, wherein the condition is such that the optical path L₂ and the sum Φ₂ of the phase shifts fulfill the equation 2:
2L₂=mλ+(Φ₂/2π)λ
wherein m is a positive integer, and λ is a wavelength of light which is intended to be extracted.

7. The multicolor display device according to claim 1, wherein the plurality of organic light-emitting elements include a third organic light-emitting element which emits light of a third emission color which is other than the first emission color and the second emission color, and wherein the third organic light-emitting element has a first electrode which is comprised of a third material different in reflectance or phase shift from the first material and the second material, an organic compound layer which comprises at least a light-emitting layer, and the second electrode.

8. The multicolor organic light-emitting device according to claim 1, wherein the organic compound layers other than the light-emitting layers comprises a film continuously formed extending over the first organic light-emitting element, the second organic light-emitting element, and the third organic light-emitting element, and wherein the film thicknesses of the organic compound layers other than the light-emitting layers are the same irrespective of the emission color.
